(19) United States
(12) Patent Application Publication
(10) Pub. No.: US 2005/0084989 A1
(43) Pub. Date: Apr. 21, 2005

(54) Semiconductor device manufacturing method

(75) Inventors: Takeshi Wakabayashi, Sayama-shi (JP); Ichiro Mihara, Tokyo (JP)

Correspondence Address: FRISHAUF, HOLTZ, GOODMAN & CHICK, PC, 767 THIRD AVENUE, 25TH FLOOR, NEW YORK, NY, 10017-2023, US

(73) Assignee: CASIO COMPUTER CO., LTD., Tokyo (JP)

(21) Appl. No.: 10/964,019

(22) Filed: Oct. 12, 2004

(30) Foreign Application Priority Data
Oct. 15, 2003 (JP) 2003-354680

(51) Int. Cl. H01L 21/66

(52) U.S. Cl. 438/14

(57) ABSTRACT

After columnar electrodes and a sealing film are formed above a semiconductor substrate in a wafer state, probe pins are brought into contact with the upper surfaces of the columnar electrodes, and burn-in is executed. Next, solder balls are formed on the columnar electrodes, and the semiconductor substrate in a wafer state is diced. As a result, any unwanted deformation of the solder balls by contact of the probe pins can be prevented. In addition, even when the heights of the solder balls vary, burn-in can be performed.

### CROSS-REFERENCE TO RELATED APPLICATIONS

This application is based upon and claims the benefit of priority from prior Japanese Patent Application No. 2003-354680, filed Oct. 15, 2003, the entire contents of which are incorporated herein by reference.

### BACKGROUND OF THE INVENTION

1. Field of the Invention

The present invention relates to a semiconductor device manufacturing method.

2. Description of the Related Art

In the field of semiconductor technology such as LSIs, burn-in is done to guarantee the reliability. Conventionally, semiconductor devices which have been diced into individual devices are subjected to burn-in (e.g., Jpn. Pat. Appln. KOKAI Publication No. 2003-282814). In this case, the efficiency is low because burn-in is executed for semiconductor devices diced into individual devices.

On the other hand, there are semiconductor devices generally called CSP (Chip Size Package) (e.g.,. Pat. Appln. KOKAI Publication No. 2002-231854). In this semiconductor device, an insulating film is formed on the upper surface of a semiconductor substrate having a plurality of connection pads. Opening portions are formed in the insulating film at positions corresponding to the connection pads. Wirings are formed on the upper surface of the insulating film and electrically connected to the connection pads through the opening portions. Columnar electrodes are formed on the upper surfaces of the connection pad portions of the wirings. A sealing film is formed on the upper surface of the insulating film including the wirings such that the upper surface becomes flush with the those of the columnar electrodes. Solder balls are formed on the exposed upper surfaces of the columnar electrodes.

When burn-in is to be executed for a semiconductor device having solder balls, as described in Jpn. Pat. Appln. KOKAI Publication No. 2002-231854, probe pins are brought into contact with the solder balls. However, when the probe pins come into contact with relatively soft solder balls, the solder balls may deform. Because of this deformation, the positions of the solder balls are erroneously recognized by an alignment camera. When such a semiconductor device is jointed to a circuit board, alignment failures may occur, and accordingly, bonding failures may occur. In addition, the recesses in the solder balls generate a variation in height between the solder balls of the semiconductor device. For this reason, failures occur in contact between the probe pins and the solder balls so that no appropriate burn-in is executed for some devices.

### BRIEF SUMMARY OF THE INVENTION

It is an object of the present invention to provide a semiconductor device manufacturing method which can execute burn-in without deforming solder balls so that burn-in can reliably be executed, and the bonding reliability can be increased.

According to an aspect of the present invention, there is provided a manufacturing method comprising forming a plurality of columnar electrodes on one side of a semiconductor substrate or wafer with integrated circuits and a sealing film on the side of the semiconductor substrate around the columnar electrodes while exposing upper surfaces of the columnar electrodes, bringing a probe pin of a test jig into contact with the upper surface of each columnar electrode and executing burn-in of the integrated circuits, and after burn-in is ended, forming a solder layer on the upper surface of each columnar electrode and dicing the semiconductor substrate to obtain individual semiconductor devices, each of the semiconductor devices having at least one integrated circuit.

According to the method, before formation of the solder balls, burn-in is executed for the semiconductor substrate in a wafer state while bringing the probe pins into contact with the upper surfaces of the columnar electrodes. Hence, any unwanted deformation of the solder balls by contact of the probe pins can be prevented. As a result, burn-in can reliably be executed, and the bonding reliability can be increased.

Additional objects and advantages of the invention will be set forth in the description which follows, and in part will be obvious from the description, or may be learned by practice of the invention. The objects and advantages of the invention may be realized and obtained by means of the instrumentalities and combinations particularly pointed out hereinafter.

### BRIEF DESCRIPTION OF THE SEVERAL VIEWS OF THE DRAWING

The accompanying drawings, which are incorporated in and constitute a part of the specification, illustrate presently preferred embodiments of the invention, and together with the general description given above and the detailed description of the preferred embodiments given below, serve to explain the principles of the invention.

FIG. 1 is a sectional view of a semiconductor device manufactured by a manufacturing method according to an embodiment of the present invention;

FIG. 2 is a sectional view of an assembly prepared first in manufacturing the semiconductor device shown in FIG. 1;

FIG. 3 is a sectional view of the assembly following the step shown in FIG. 2;

FIG. 4 is a sectional view of the assembly following the step shown in FIG. 3;

FIG. 5 is a sectional view of the assembly following the step shown in FIG. 4;

FIG. 6 is a sectional view of the assembly following the step shown in FIG. 5;

FIG. 7 is a sectional view of the assembly following the step shown in FIG. 6; and

FIG. 8 is a sectional view of the assembly following the step shown in FIG. 7.

### DETAILED DESCRIPTION OF THE INVENTION

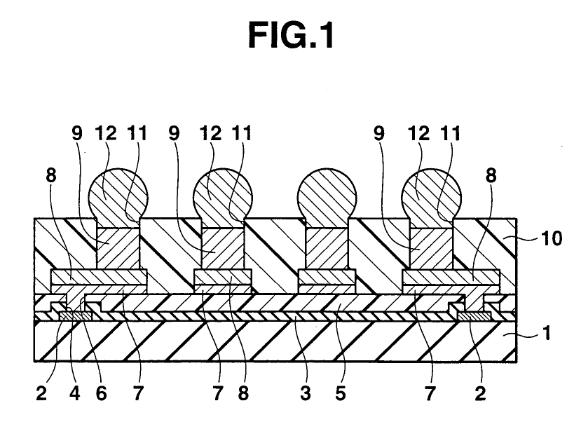

FIG. 1 is a sectional view of a semiconductor device manufactured by a manufacturing method according to an embodiment of the present invention. This semiconductor device comprises a semiconductor substrate or wafer 1 made of, for example, silicon. An integrated circuit (not shown) having a predetermined function is arranged on the upper surface of the semiconductor substrate 1. A plurality of connection pads 2 made of an aluminum-based metal are formed at the peripheral portion of the upper surface and electrically connected to the integrated circuit. An insulating film 3 made of silicon oxide is formed on the upper surface of the semiconductor substrate 1 except the central portions of the connection pads 2. The central portions of the connection pads 2 are exposed through opening portions 4 formed in the insulating film 3.

A protective film (insulating film) 5 made of epoxy resin or polyimide resin is formed on the upper surface of the insulating film 3. In this case, the protective film 5 has opening portions 6 at positions corresponding to the opening portions 4 of the insulating film 3. Undercoating metal layers 7 made of, for example, copper are formed on the upper surface of the protective film 5. Wirings 8 made of metal, for example, copper are formed on the entire upper surfaces of the undercoating metal layers 7. One end portion of each wiring 8 including the undercoating metal layer 7 is electrically connected to a corresponding connection pad 2 through the opening portions 4 and 6.

Columnar electrodes 9 made of copper are formed on the upper surfaces of the connection pad portions of the wirings 8. A sealing film 10 made of epoxy resin or polyimide resin is formed on the upper surface of the protective film 5 including the wirings 8 such that the upper surface is higher than those of the columnar electrodes 9. Parts of the sealing film 10 on the columnar electrodes 9 has opening portions 11 to expose the upper surfaces of the electrodes. Solder balls 12 are formed in and above the opening portions 11 and electrically and mechanically connected to the upper surfaces of the columnar electrodes 9. The height of the columnar electrodes 9 is about 80 to 150 μm.

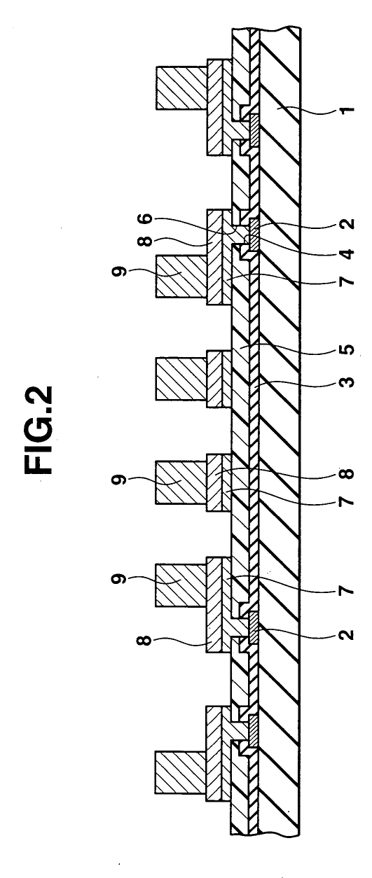

An example of the manufacturing method of the semiconductor device will be described next. First, a structure as shown in FIG. 2 is prepared, in which connection pads 2 are formed on the upper surface of a semiconductor substrate 1 in a wafer state which includes a plurality of integrated circuits (not shown). An insulating film 3 and protective film 5 are formed on the upper surface, in this order. Wirings 8 including undercoating metal layers 7 are formed on the upper surface of the protective film 5 and connected to the connection pads 2 through opening portions 4 and 6 respectively formed in the insulating film 3 and protective film 5. Columnar electrodes 9 are formed on the upper surfaces of the connection pad portions of the wirings 8. In this case, the columnar electrodes 9 are formed such that their height becomes about 95 to 165 μm.

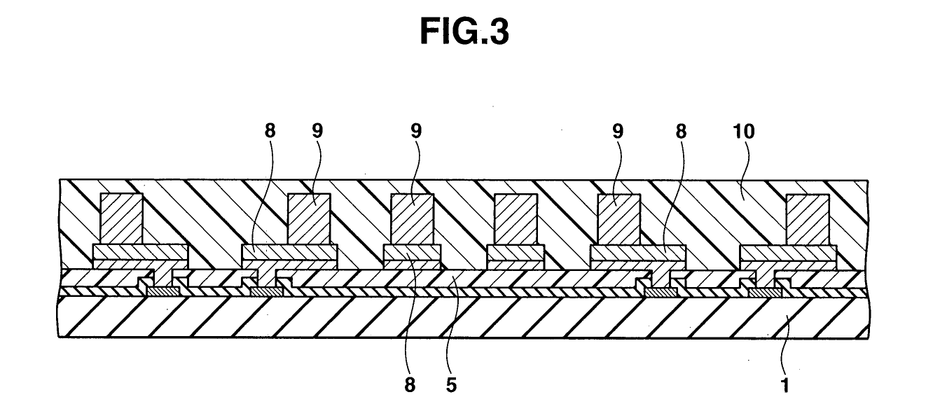

As shown in FIG. 3, a sealing film 10 made of epoxy resin or the like is formed on the entire upper surface of the protective film 5 including the upper surfaces of the columnar electrodes 9 and wirings 8 by screen printing, spin coating, or die coating such that the thickness of the sealing film 10 is more than the height of the columnar electrodes 9. Hence, in this state, the upper surfaces of the columnar electrodes 9 are covered with the sealing film 10.

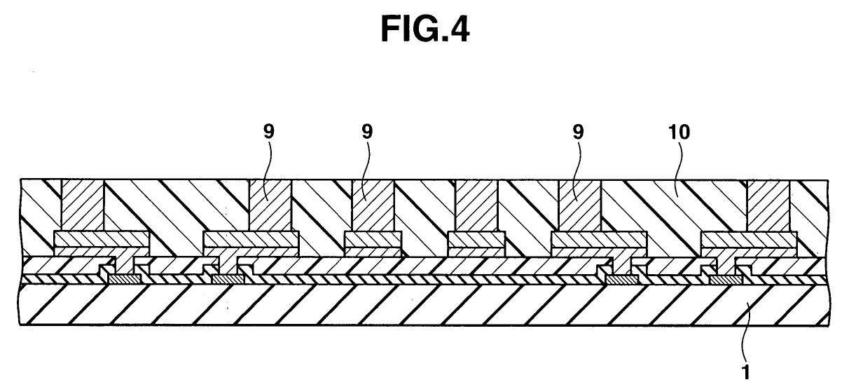

The upper surface side of the sealing film 10 and columnar electrodes 9 is appropriately polished by, e.g., about 5 to 10 μm to expose the upper surfaces of the columnar electrodes 9, as shown in FIG. 4. In addition, the upper surface of the sealing film 10 including the exposed upper surfaces of the columnar electrodes 9 is planarized. The reason why the upper surface side of the columnar electrodes 9 is appropriately polished is that the heights of the columnar electrodes 9 formed by electroplating have a variation and need to be uniformed by canceling the variation.

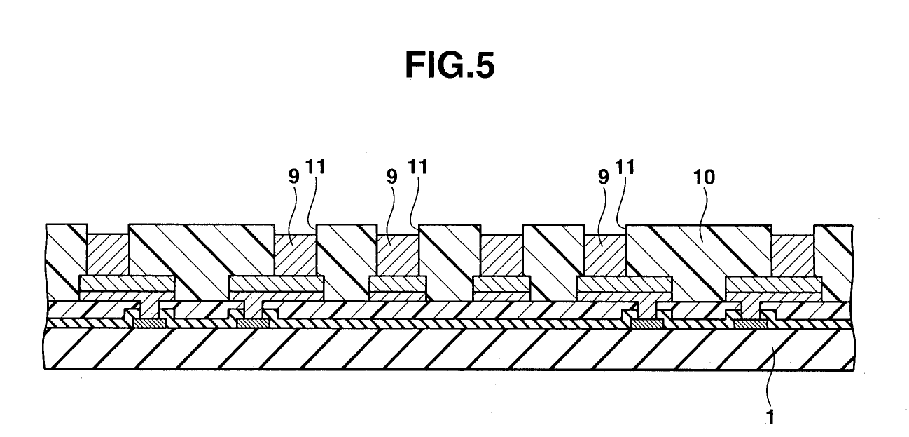

As shown in FIG. 5, the upper surface sides of the columnar electrodes 9 are slightly removed by, e.g., 5 μm by half etching to form opening portions 11 on the columnar electrodes 9. In this case, half etching for the columnar electrodes 9 is almost uniformly performed. In addition, the etching amount of about 5 μm is very small. For these reasons, the depths of the opening portions 11 are almost uniform. Accordingly, the resultant columnar electrodes 9 having a height of about 80 to 150 μm are formed.

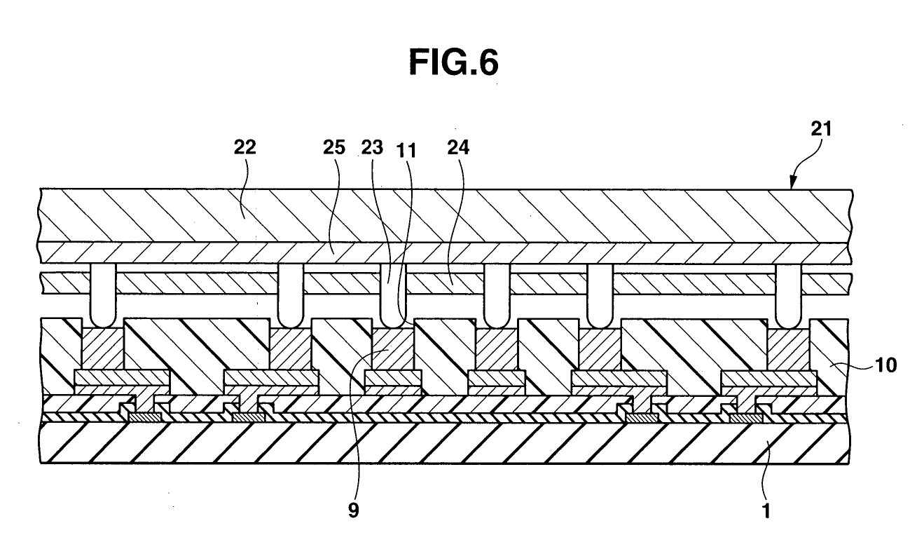

As shown in FIG. 6, a burn-in test jig 21 is prepared. In the burn-in test jig 21, a probe pin support plate 24 having a plurality of probe pins 23 is arranged on the lower surface side of a wiring board 22 with wirings (not shown) on its lower surface. The upper end faces of the probe pins 23 are connected to the wirings of the wiring board 22 through an anisotropic conductive rubber 25. In this case, the distal end portions of the probe pins 23 have an almost hemispherical shape. The diameter of the probe pins 23 is slightly smaller than that of the opening portions 11 of the sealing film 10.

The distal ends of the probe pins 23 of the burn-in test jig 21 are brought into contact with the upper surfaces of the columnar electrodes 9 in the opening portions 11 of the sealing film 10 on the semiconductor substrate 1 in a wafer state which is arranged on a stage (not shown). Then, burn-in is executed. In this case, since the depths of the opening portions 11 of the sealing film 10 are almost uniform, the distal ends of the probe pins 23 can reliably be brought into contact with the upper surfaces of the columnar electrodes 9 in the opening portions 11. Hence, any electrical connection failures can reliably be prevented.

In addition, the diameter of the probe pins 23 is slightly smaller than that of the opening portions 11 of the sealing film 10. For this reason, even when the probe pins 23 are misaligned to the opening portions 11 to some extent, the distal end portions of the probe pins 23 can reliably be arranged in the opening portions 11. Furthermore, even when the probe pins 23 slightly slide during measurement, they abut against the inner wall surfaces of the opening portions 11. Hence, the electrical contact between the distal ends of the probe pins 23 and the upper surfaces of the columnar electrodes 9 can reliably be maintained.

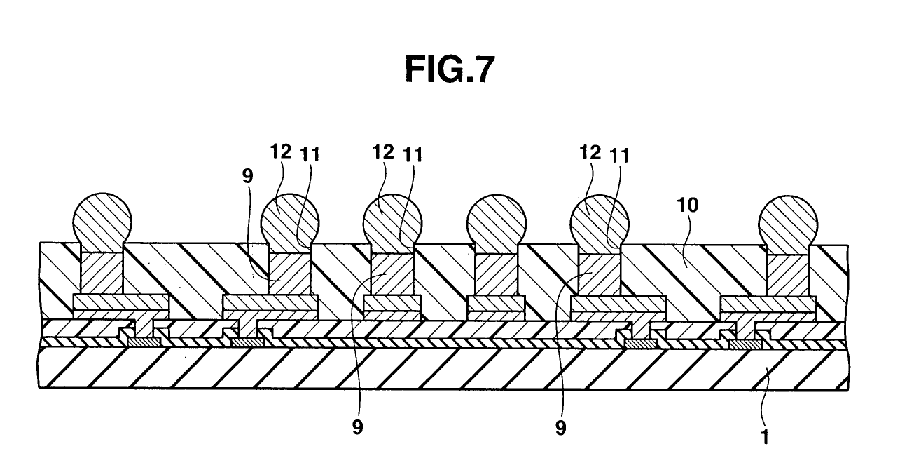

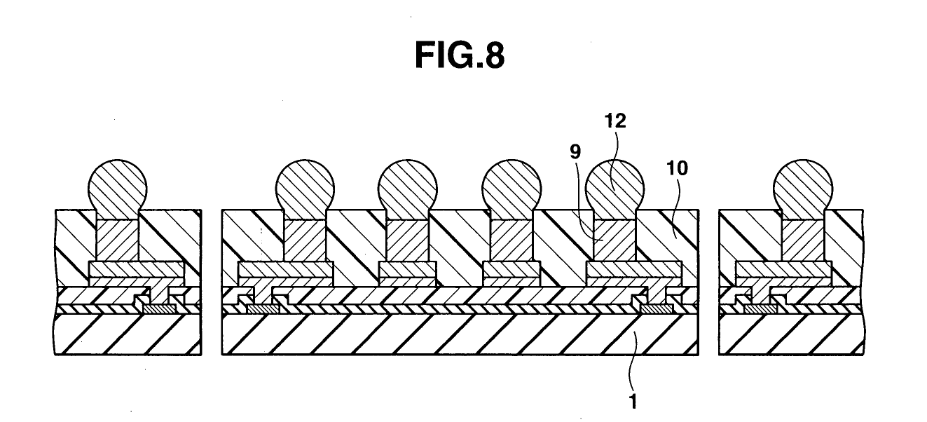

When burn-in is ended, solder balls 12 are formed in and above the opening portions 11 and connected to the upper surfaces of the columnar electrodes 9, an electrical/mechanical relation ship as shown in FIG. 7. Next, the lower surface of the semiconductor substrate 1 is bonded to a dicing tape (not shown). After the dicing step shown in FIG. 8, the structures are peeled from the dicing tape. Accordingly, a plurality of semiconductor devices, each including at least one integrated circuit as shown in FIG. 1 are obtained.

As described above, in the semiconductor device manufacturing method, before formation of the solder balls 12, burn-in is executed while bringing the probe pins 23 into contact with the upper surfaces of the columnar electrodes 9. Hence, burn-in can be executed without bringing the probe pins 23 into contact with the solder balls 12. As a result, any unwanted deformation of the solder balls 12 can be prevented. In addition, even when the heights of the solder balls 12 vary, burn-in can be performed. Furthermore, since the semiconductor substrate 1 in a wafer state is subjected to burn-in, the efficiency is high.

Unlike the above-described method, after burn-in shown in FIG. 6 is executed, native oxide films formed on the upper surfaces of the columnar electrodes 9 may be removed by a short-time etching, and then, solder balls 12 may be formed on the upper surfaces of the columnar electrodes 9. After the step shown in FIG. 5, electroless plating of nickel/gold, nickel/solder, or nickel/tin may be performed to form anti-oxidation surface treatment layers on the upper surfaces of the columnar electrodes 9, and then, burn-in may be executed. In this case, the upper surfaces of the surface treatment layers may be slightly lower than that of the sealing film 10 such that the opening portions 11 remain in the sealing film 10 on the surface treatment layers. Alternatively, after the step shown in FIG. 4, burn-in may be executed. Then, solder balls 12 may be formed on the upper surfaces of the columnar electrodes 9 which are flush with that of the sealing film. 10 without half-etching the upper surface sides of the columnar electrodes 9. Even in this case, the native oxide films formed on the upper surfaces of the columnar electrodes 9 may be removed by etching. After that, surface treatment layers may be formed, and then, burn-in may be executed.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

1. A method for manufacturing a semiconductor device comprising:
forming a plurality of columnar electrodes on one side of a semiconductor substrate with integrated circuits and a sealing film on the semiconductor substrate around the columnar electrodes while exposing upper surfaces of the columnar electrodes;
bringing a probe pin of a test jig into contact with the upper surface of each columnar electrode and executing burn-in of the integrated circuits; and
after burn-in is ended, forming a solder layer on the upper surface of each columnar electrode and dicing the semiconductor substrate to obtain individual semiconductor devices, each of the semiconductor devices having at least one integrated circuit.

2. A method according to claim 1, further comprising polishing an upper surface side of the sealing film to expose the upper surfaces of the columnar electrodes and then forming a surface treatment layer on the exposed upper surface of each columnar electrode.

3. A method according to claim 1, wherein forming the plurality of columnar electrodes and the sealing film on said one side of the semiconductor substrate includes forming the sealing film on said one side of the semiconductor substrate having the columnar electrodes to cover the upper surfaces of the columnar electrodes and polishing an upper surface side of the sealing film to expose the upper surfaces of the columnar electrodes.

4. A method according to claim 3, further comprising, after polishing the upper surface side of the sealing film to expose the upper surfaces of the columnar electrodes, making the upper surface of each columnar electrode lower than the upper surface of the sealing film.

5. A method according to claim 4, further comprising, after making the upper surface of each columnar electrode lower than the upper surface of the sealing film, removing a native oxide film formed on the upper surface of each columnar electrode.

6. A method according to claim 4, further comprising, after making the upper surface of each columnar electrode lower than the upper surface of the sealing film, forming a surface treatment layer on the upper surface of each columnar electrode.

7. A method according to claim 1, wherein forming the plurality of columnar electrodes and the sealing film on the semiconductor substrate includes making the upper surface of each columnar electrode flush with the upper surface of the sealing film and making the upper surface of each columnar electrode lower than the upper surface of the sealing film.

8. A method according to claim 1, wherein the solder layer comprises a solder ball.

9. A semiconductor device manufacturing method comprising:
preparing a semiconductor substrate having integrated circuits;
forming a plurality of columnar electrodes on one side of the semiconductor substrate;
forming a sealing film on said one side of the semiconductor substrate around the columnar electrodes while exposing upper surfaces of the columnar electrodes;
forming a surface treatment layer on the upper surface of each columnar electrode;
preparing a test jig on which a plurality of probe pins are arrayed while making each of the plurality of probe pins correspond to one of the columnar electrodes, bringing each of the probe pins into contact with a corresponding one of the columnar electrodes, and executing burn-in for the integrated circuits in this state;
after burn-in is ended, forming a solder ball on the upper surface of each columnar electrode; and
dicing the semiconductor substrate to obtain individual semiconductor devices, each of the semiconductor devices having at least one integrated circuit.
